(19) United States
(12) Patent Application Publication
(10) Pub. No.: US 2025/0273555 A1
(43) Pub. Date: Aug. 28, 2025

(54) Component Carrier with Ultra-thin Insulation Film and Manufacturing Method

(71) Applicant: AT&S Austria Technologie & Systemtechnik AG, Leoben (AT)

(72) Inventor: Daniel ZHANG, Chongqing (CN)

(21) Appl. No.: 18/585,434

(22) Filed: Feb. 23, 2024

(51) Int. Cl. H01L 23/498; H01L 21/48; H01L 23/00

(52) U.S. Cl. CPC H01L 23/49838; H01L 21/4846; H01L 23/49894; H01L 24/16; H01L 23/49827; H01L 2224/16227

(57) ABSTRACT

A component carrier including i) an inorganic carrier structure; ii) an electrically insulating layer structure comprising resin and reinforcing structures on the inorganic carrier structure; iii) an ultra-thin insulation film on the electrically insulating layer structure; and iv) an electrically conductive structure with a fine line pattern directly on the ultra-thin insulation film.

### TECHNICAL FIELD

Embodiments of the disclosure relate to the technical field of component carriers, such as printed circuit boards or IC substrates, and their manufacture.

### TECHNOLOGICAL BACKGROUND

In the context of growing product functionalities of component carriers equipped with one or more electronic components and increasing miniaturization of such electronic components as well as a rising number of electronic components to be mounted on the component carriers such as printed circuit boards, increasingly more powerful array-like components or packages having several electronic components are being employed, which have a plurality of contacts or connections, with ever smaller spacing between these contacts. Removal of heat generated by such electronic components and the component carrier itself during operation becomes an increasing issue. Also, an efficient protection against electromagnetic interference (EMI) becomes an increasing issue. At the same time, component carriers shall be mechanically robust and electrically and magnetically reliable to be operable even under harsh conditions.

In particular, providing a component carrier with fine-line pattern metal traces on the one hand, and a high stiffness (stability) on the other hand, may be considered a challenge.

FIG. 3 shows a cross-section through a conventional circuit board 200. The circuit board 200 comprises a glass core 210 with an insulation layer 220 (Ajinomoto build-up film, ABF) on top. Further on top, there is provided a solder resist layer 250. On top of the circuit board 200, there is arranged an IC chip 260. In order to electrically connect the IC chip 260 with circuit board 200 stack, solder balls 265 are formed that electrically connect IC chip pads 261 with component carrier pads 242. The component carrier pads 242 are part of a patterned copper layer 240 on top of the insulation layer 220 and embedded in the solder resist material 250. The component carrier pads 242 are further connected by blind laser vias to further component carrier pads 286 on the glass core 210, and embedded in the insulation layer 220. The embedded component carrier pads of the patterned copper layer 240 can be manufactured by a semi-additive process (SAP) on top of the ABF layer 220.

FIG. 4 shows a variation of FIG. 3 with a further insulation layer 280 (ABF) between the insulation layer 220 and the glass core 210. Thereby, the further component carrier pads 286 are embedded within the insulation layer material (ABF).

Nevertheless, this architecture may suffer from several drawbacks, in particular regarding stability and fine line patterning of the metal traces.

In the first place, in order to form the further component carrier pads 186, a seed layer is formed on the glass core 210. This is conventionally done by sputter Ti/Cu or high-build electroless copper processes, leading to high costs.

In the second place, the formation of fine-line structures may be limited by the insulation layer 220 (ABF) formation, e.g. conventionally done by SAP.

Additionally, stiffness may be limited and this issue may further lead to easy cracking in case of multiple layers or thermal impact.

### SUMMARY

There may be a need to provide a component carrier with fine-line patterning and high stability in an efficient and reliable manner.

A component carrier and a manufacturing method are described.

According to a first aspect of the disclosure, there is described a component carrier (e.g., a printed circuit board, an IC substrate, an interposer), wherein the component carrier comprises (a stack with): i) an inorganic carrier structure (e.g. a glass core layer); ii) an (organic) electrically insulating layer structure comprising resin (e.g. epoxy resin) and reinforcing structures (e.g., glass fibers) (e.g., provided as prepreg) on the inorganic carrier structure; iii) an ultra-thin insulation film on the electrically insulating layer structure; and iv) an electrically conductive (layer) structure (e.g., a patterned electrically conductive layer structure, in particular metal traces) with a fine line pattern (e.g., line spacing of 10/10 μm or lower) directly on the ultra-thin insulation film.

According to a second aspect of the disclosure, there is described a method of manufacturing a component carrier, wherein the method includes i) providing an inorganic carrier structure; ii) applying (e.g., laminating) an electrically insulating layer structure (e.g., prepreg), which comprises resin and reinforcing structures, on the inorganic carrier structure; iii) applying an ultra-thin insulation film on the electrically insulating layer structure; and iv) forming an electrically conductive layer structure with a fine line pattern directly on the ultra-thin insulation film (e.g., by a SAP process).

### Overview of Embodiments

In the present context, the term “component carrier” may refer to a final component carrier product as well as to a component carrier preform (i.e. a component carrier in production, in other words a semi-finished product). In an example, a component carrier preform may be a panel that comprises a plurality of semi-finished component carriers that are manufactured together. At a final stage, the panel may be separated into the plurality of final component carrier products.

In an embodiment, the component carrier “stack” comprises at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components. In an example, the stack may be nevertheless very thin and compact. In another example, the stack may be very thick for a high-density product. The stacking direction (height/thickness) may be arranged in the vertical direction z. Further, the stacking direction may be perpendicular to the two orthogonal directions of main extension (along an x-direction and along a y-direction) of the (plate-shaped) component carrier. In an example, all layers of the component carrier may form the stack. In another example, only a part of the layers of the component carrier form the stack. In this context, the term “layer structure” may in particular refer to a continuous or discontinuous layer (or separated islands within the same plane) of electrically conductive or electrically insulating material. A plurality of such layers, parallel stacked one upon the other, may form the stack in the vertical direction.

In the present context, the term “electrically conductive layer structure” may refer to an electrically conductive structure (e.g., a metal, in particular copper, more in particular for of a copper foil, or carbon, in particular graphene, e.g., as a layer) which has been patterned, e.g., by a subtractive method or an additive method, such as (wet or plasma) etching. After patterning, the electrically conductive structure may for example comprise a plurality of electrically conductive (metal, e.g., copper) traces and/or pads and/or interconnections, and/or conductive paths/areas. In this manner, electrical connection within the component carrier can be provided.

In the present context, the term “inorganic carrier structure” may refer to a (layer) structure suitable to function as a support (base layer) for a layer build-up (e.g., an electrically insulating layer structure and/or a solder resist layer structure). The inorganic carrier structure preferably comprises or consists of an inorganic material, for example glass, ceramic, quartz or a semiconductor material. Thus, the inorganic carrier structure may be (essentially) free of organic materials such as resin. In an example, at least one via connection (e.g., through/blind via) may be formed through the inorganic carrier structure for electrical connection within the component carrier stack.

In the present context, the term “ultra-thin insulation film” may refer to a layer structure (in particular a foil-like structure) that comprises or consists of electrically insulating (dielectric) material. In an embodiment, the term “ultra-thin” may in particular refer to a thickness in a range from 1 μm to 20 μm, in particular 2 μm to 15 μm. Preferably, the ultra-thin insulation film is configured to enable a high adhesion to the electrically conductive layer structure directly on top. This may be realized for example by a high surface roughness. The ultra-thin insulation film may be a mixture of different materials, e.g., a composite. For example, the ultra-thin insulation film may comprise a polymer mixture, e.g., a rigid thermosetting resin and/or a reactive low polar polymer. Further, the ultra-thin insulation film may comprise filler (particles), e.g., inorganic fillers. In an example, the ultra-thin insulation film comprises a low CTE (coefficient of thermal expansion) material (e.g., around 18 ppm/° C.). In an example, the ultra-thin insulation film may be provided with a thin metal (copper) foil (e.g., in a range 1 to 3 μm thickness) for protection and/or for generating the high surface roughness (as a mirror image to a high surface roughness of the thin metal foil). The metal layer may function as a seed layer or may be removed (by etching) to enable formation of another seed layer. The ultra-thin insulation film may function as a primer in a SAP or mSAP process (or a primer SAP (pSAP) process).

According to an exemplary embodiment, the disclosure illustrates and describes that a component carrier with fine-line pattern (of metal traces) and high stiffness/stability can be provided in an efficient and reliable manner, when an electrically conductive layer structure with a fine line pattern is formed directly on a ultra-thin insulation film, which is further based on a reinforced resin layer and an inorganic carrier structure.

While conventionally, fine line space traces are formed directly on an ABF material (see FIGS. 3 and 4), it has been found by the inventors that an especially stable and (cost-) efficient architecture may be enabled by forming the fine line pattern on a (glass-fiber) reinforced resin layer (supported by the inorganic carrier) with the ultra-thin insulation film directly in between.

The ultra-thin insulation film may provide an especially high adhesion of the fine line pattern structure at a low cost. The inorganic carrier structure and the reinforced resin layer structure may form a stable, highly stiff, and low-cost support structure, in particular with electric connection pads/traces on top. The reinforced resin layer structure may be provided as a thin layer with high stiffness and thermal withstand capability.

The described architecture further enables a high design flexibility, since properties such as the CTE may be modified in a straightforward manner. Additionally, corresponding manufacturing methods may be directly implemented into existing component carrier production lines.

In an embodiment, the inorganic carrier structure comprises at least one of a glass, a ceramic, a semiconductor material. This may provide the advantage that a stable and flexibly applicable layer structure is provided, in particular as a robust support.

In the context of the present application, the term “glass structure” may particularly denote a body configured for being inserted into a destination and comprising glass as a main constituent. For example, the glass structure may be a block or plate. The major material component (in particular the material component of the glass structure providing the highest weight percentage) of the glass structure is glass, for example silicon-based glass, in particular soda lime glass, and/or boro-silicate glass and/or alumo-silicate glass and/or lithium silicate glass and/or alkaline free glass. For instance, at least 90 weight percent of the glass structure may be glass. For example, the glass structure may consist only of glass, apart from a patterned metal layer thereon. It is however also possible that the glass structure comprises one or more additional other materials. For instance, further electrically conductive (for example comprising metal and/or metal alloys, for example, copper and/or tin and/or bronze and/or conductive paste) structures (such as wiring traces and/or vertical through connections) may be integrated in a main glass body of the glass structure and/or may be formed on a surface of a main glass body.

Moreover, the glass structure can also be provided with a heat dissipation and power supply function with specific structure inside. It is however also possible that the glass structure comprises ceramic material, for example aluminum nitride and/or aluminum oxide and/or silicon nitride and/or boron nitride and/or tungsten comprising ceramic material. Additionally, and/or alternatively, the glass structure may comprise semi-conductive material, for example silicon and/or germanium and/or silicon oxide and/or germanium oxide and/or silicon carbide and/or gallium nitride. Yet it is further possible, that the glass structure may comprise inorganic material, which is not listed in the above-mentioned examples, such as: MoS₂, CuGaO₂, AgAlO₂, LiGaTe₂, AgInSe₂, CuFeS₂, BeO.

In an embodiment, the resin of the electrically insulating layer structure comprises an epoxy resin. This may provide the advantage that a well-established and economically important material can be directly applied. The epoxy resin (with reinforcement structures) may be present/provided in an uncured state (prepreg) or in a (fully) cured state.

In an embodiment, the reinforcing structures of the electrically insulating layer structure comprise reinforcing fibers, in particular glass fibers, more in particular glass cloth. Thereby, a high stability and stiffness may be achieved in a cost-efficient and reliable manner.

In an embodiment, the ultra-thin insulation film has a thickness in a range from 2 μm to 15 μm, in particular 2 μm to 10 μm, more in particular around 4 μm. This may provide the advantage that an extremely thin (ultra-thin) layer (film/foil) may be provided that may nevertheless efficiently function as a primer (seed layer) for the fine line pattern electrically conductive layer structure.

In an embodiment, the ultra-thin insulation film has a first surface roughness higher (or equal or lower) than a second surface roughness of the electrically insulating layer structure and/or higher (or equal or lower) than a third surface roughness of the electrically conductive fine line pattern and/or higher (or equal or lower) than a fourth surface roughness of the further electrically insulating layer structure. A larger surface roughness may enable an improved adhesion of electrically conductive material, thereby eventually enabling a smaller fine line pattern.

In a specific example, the first surface roughness may be in the range of 0.2 to 0.5 μm (Ra), 1.0 to 2.5 μm (Rz). The second/fourth surface roughness may be for example in the range of 0.2 to 0.3 μm (Ra), 2 to 3 μm (Rz). The difference may be the Rsar ratio (relative surface area increase ratio). A large Rsar may be advantageous in the present context. In an example, the ultra-thin insulation film Rsar may be 100% to 300%, while the (further) electrically insulating layer structure Rsar may be less than 50%.

In an embodiment, the ultra-thin insulation film is formed in contact with, in particular directly on, the electrically insulating layer structure. This may provide the advantage that the ultra-thin layer film functions as an interposer layer between the electrically insulating layer structure (prepreg) and the electrically conductive layer structure (metal traces), providing an improved adhesion of the electrically conductive material; yet being so thin that no additional influence may be caused.

In an embodiment, the fine line pattern of the electrically conductive layer structure comprises at least one (metal/copper) trace (in particular a plurality of traces) having a width in a range from 3 μm to 15 μm, in particular 3 to 10 μm. This may provide the advantage that a very small fine line pattern is provided. In an example, the trace width and space between traces may be both be in the range 3 μm to 15 μm. Thus, a very fine line spacing may be provided, for example 10/10 μm L/S or 8/8 μm L/S (or lower). For a line spacing below 8/8 μm, additional Ti/Cu sputter technology may be used.

In an embodiment, the fine line pattern of the electrically conductive layer structure has a thickness in a range from 3 μm to 15 μm. This may also provide the advantage that a very small fine line pattern is provided.

In an embodiment, the (further) electrically insulating layer structure is formed directly on the inorganic carrier structure. Thereby, a compact and stable build-up may be provided, e.g., by lamination.

In an embodiment, the component carrier further includes a (surface-mounted) electronic component (e.g., a semiconductor element, like an IC) being electrically coupled with the fine line pattern of the electrically insulating layer structure by an electrically conductive connection structure, in particular a solder structure. Hence, an electronic component may be electrically connected to the component carrier stack in an efficient and reliable manner. The electrically conductive connection structure may connect a pad/trace/terminal of the electronic component with a pad/trace/terminal of the component carrier stack, in particular a part of the electrically conductive layer structure (at the fine line pattern or adjacent to the fine line pattern). In an example, the electrically conductive connection structure may be (at least partially) embedded in a dielectric material, e.g., the solder resist layer structure.

In an embodiment, the component carrier further includes a dielectric layer, in particular a solder resist layer structure, arranged on (and embedding/encapsulating) the fine line pattern structure of the electrically conductive layer structure. In an embodiment, the solder resist layer structure has a thickness in a range from 5 μm to 20 μm. This may provide the advantage that the solder resist layer structure may protect efficiently the fine line pattern structure, still enabling a stable electric connection.

In an embodiment, the component carrier further includes a further electrically insulating layer structure comprising a further resin and further reinforcing structures on the inorganic carrier structure. In an embodiment, the component carrier further includes a further ultra-thin insulation film on said further electrically insulating layer structure. In an embodiment, the component carrier further includes a further electrically conductive layer structure (directly) on the further ultra-thin insulation film. In an embodiment, the further electrically insulating layer structure and the further ultra-thin insulation film are arranged between the inorganic carrier structure and the electrically insulating layer structure. The above-described advantages of the ultra-thin insulation layer (on an electrically insulating layer structure) may apply in the same manner within the component carrier stack. Thereby, a further electrically conductive layer structure (in particular with a fine line pattern), embedded in the component carrier stack, may be provided in an efficient and reliable manner (and with a good adhesion) on the ultra-thin insulation film.

The further electrically conductive layer structure can be much closer to the glass core, therefore it may share the benefit brought by the glass core, i.e. glass stiffness and low coefficient of thermal expansion ratio. This may provide the advantage that the glass core (and the further insulating layer structure) are superior to organic base substrates.

In an embodiment, the component carrier further includes an electrically conductive vertical through-connection, extending through at least one of the inorganic carrier structure, the electrically insulating layer structure, the ultra-thin insulation film. Thereby, an efficient and reliable electrical (inter-) connection may be enabled. It also provides a direct electrical connection for the stack on both sides of the inorganic component structure. Thereby, the signal transmission path for the two stacks may be shortened and may increase the density of conductive structure for higher performance of the component carrier.

In an example, the electrically conductive vertical through-connection may be configured as a through via that extends through two or more layers. In another example, the electrically conductive vertical through-connection may be realized by at least one pad and at least one via. For example, respective blind vias may extend through the inorganic carrier structure and/or the electrically insulating layer structure. At the interface of said layers, pads/traces may be formed (e.g., by a respective electrically conductive layer structure) to enable an interconnection of the vias.

In an embodiment, the component carrier further includes an intermingling region at an interface between the electrically insulating layer structure and the ultra-thin insulation film, wherein the intermingling region comprises a mixture of material of the electrically insulating layer structure and material of the ultra-thin insulation film. The two materials might penetrate with each other, so there might be a merge surface between the two layers and the portion or filling material such that separate materials respectively protrude into the other material. Such a structural feature may reflect a manufacture step of forming the ultra-thin insulation film on the electrically insulating layer structure, e.g., by a lamination process. Further, the adhesion between the electrically insulating layer structure and the ultra-thin insulation film may be improved by the intermingling region.

In an embodiment, the component carrier further includes a base structure beneath the inorganic carrier structure. Thereby, a stable and robust component carrier may be provided. The base structure may be, for example, a carrier structure (e.g., a core structure) or a further stack.

In an embodiment, the ultra-thin insulation film comprises at least one of the following materials: a polymer (e.g., a (rigid) thermosetting resin, a reactive (low polar) polymer), a filler (e.g., an organic or an inorganic filler). Depending on the desired application, the composition of the ultra-thin insulation film may be adjusted. Based on the adjustment, the electrical performance and/or mechanical performance may be increased.

In an example, the ultra-thin insulation film comprises a rigid thermosetting resin with at least one of the following properties: low Df, high Tg, low CTE, high elastic modulus, high heat resistance, high flame retardancy. In an example, the ultra-thin insulation film comprises a reactive polymer with at least one of the following properties: high adhesion, low Dk, low Df, high Tg, low water absorption, high toughness, low polarity. In an example, the ultra-thin insulation film comprises a filler with at least one of the following properties: low CTE, low Df, high heat resistance, low water absorption.

In an embodiment, the method further includes applying an electrically conductive material for forming the electrically conductive layer structure with the fine line pattern structure on the ultra-thin insulation film by at least one of electroless deposition, plating, sputtering, laminating a metal foil. Using established and reliable techniques of the component carrier manufacture process, the fine line pattern structure of the electrically conductive layer structure may be formed in a cost-efficient manner (see e.g., FIGS. 5A to 5H).

In an embodiment, the method further includes applying the ultra-thin insulation film in an at least partially uncured state. Thereby, the film may be distributed in a homogenous manner and the component carrier may be easier to manufacture. The film may be cured at a later stage, before or after providing the electrically conductive material for forming the electrically conductive layer structure with the fine line pattern structure on the ultra-thin insulation film. In an example, a high surface roughness of the ultra-thin insulation film may be provided in the uncured state, e.g., by a corresponding metal layer with a high surface roughness.

In an embodiment, the CTE of the ultra-thin insulation film may be around 18 ppm/° C. For the whole structure, e.g., using glass cloth prepreg as the electrically insulating layer structure, the CTE (Z) may be in the range 8 to 45 ppm/° C. and the CTE (X/Y) may be in the range 3 to 17 ppm/° C.

In an embodiment, the component carrier is shaped as a plate. This contributes to the compact design, wherein the component carrier nevertheless provides a large basis for mounting components thereon. Furthermore, in particular a bare die as example for an embedded electronic component, can be conveniently embedded, thanks to its small thickness, into a thin plate such as a printed circuit board.

In an embodiment, the component carrier is configured as one of the group consisting of a printed circuit board, a substrate (in particular an IC substrate), and an interposer.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in case of a Chip Scale Package (CSP)). More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

In the context of the present application, the term “inorganic layer structure” may particularly denote a layer structure which comprises inorganic material, such as an inorganic compound. In particular, dielectric material of the inorganic layer structure or even the entire inorganic layer structure may be made exclusively or at least substantially exclusively from inorganic material. In another embodiment, the inorganic layer structure may comprise inorganic dielectric material and additionally another dielectric material. An inorganic compound may be a chemical compound that lacks carbon-hydrogen bonds or a chemical compound that is not an organic compound. In an example, the inorganic layer structure may comprise glass, for example silicon base glass, in particular soda lime glass, and/or boro-silicate glass and/or alumo-silicate glass and/or lithium silicate glass and/or alkaline free glass. In another example, the inorganic layer structure may comprise ceramic material, for example aluminum nitride and/or aluminum oxide and/or silicon nitride and/or boron nitride and/or tungsten comprising ceramic material. Yet, in another example, the inorganic layer structure may comprise semi-conducting material, for example silicon and/or germanium and/or silicon oxide and/or germanium oxide and/or silicon carbide and/or gallium nitride. In a further embodiment, the inorganic layer structure may comprise (elemental) metal and/or metal alloys, for example, copper and/or tin and/or bronze. Yet in another embodiment, the inorganic layer structure may comprise inorganic material, which is not listed in the above-mentioned example, such as: MoS₂, CuGaO₂, AgAlO₂, LiGaTe₂, AgInSe₂, CuFeS₂, BeO.

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo- and/or thermosensitive molecules) like polyimide or polybenzoxazole.

In an embodiment, the at least one electrically insulating layer structure (and/or the curable dielectric elements) comprises at least one of the group consisting of a resin or a polymer, such as epoxy resin, cyanate ester resin, benzocyclobutene resin, bismaleimide-triazine resin, polyphenylene derivate (e.g., based on polyphenylenether, PPE), polyimide (PI), polyamide (PA), liquid crystal polymer (LCP), polytetrafluoroethylene (PTFE), polyvinylidene fluoride (PVDF) and/or a combination thereof. Reinforcing structures such as webs, fibers, spheres, or other kinds of filler particles, for example made of glass (multilayer glass) in order to form a composite, could be used as well. A semi-cured resin in combination with a reinforcing agent, e.g., fibers impregnated with the above-mentioned resins is called prepreg. These prepregs are often named after their properties e.g. FR4 or FR5, which describe their flame-retardant properties. Although prepreg particularly FR4 are usually preferred for rigid PCBs, other materials, in particular epoxy-based build-up materials (such as build-up films) or photoimageable dielectric materials, may be used as well. For high frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure comprises at least one of the group consisting of copper, aluminum, nickel, silver, gold, palladium, tungsten, carbon, platinum, (doped) silicon, and magnesium. Although copper is usually preferred, other materials or coated versions thereof are possible as well, in particular coated with supra-conductive material or conductive polymers, such as graphene or poly(3,4-ethylenedioxythiophene) (PEDOT), respectively.

At least one component may be embedded in the component carrier and/or may be surface mounted on the component carrier. Such a component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be either embedded or surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SiC), gallium arsenide (GaAs), gallium nitride (GaN), gallium oxide (Ga₂O₃), indium gallium arsenide (InGaAs) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer, or a further component carrier, for example in a board-in-board configuration. The component may be surface mounted on the component carrier and/or may be embedded in an interior thereof. Moreover, other components, in particular those which generate and emit electromagnetic radiation and/or are sensitive with regard to electromagnetic radiation propagating from an environment, may be used as a component.

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable.

A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), gold (in particular hard gold), chemical tin, nickel-gold, nickel-palladium, etc.

### BRIEF DESCRIPTION OF THE DRAWINGS

The aspects defined above, and further aspects of the disclosure are apparent from the examples of embodiment to be described hereinafter and are explained with reference to these example embodiments.

FIG. 1 shows a cross-section through a component carrier, according to an exemplary embodiment of the disclosure.

FIG. 2 shows a cross-section through a component carrier, according to an exemplary embodiment of the invention, with a further electrically insulating layer structure.

FIG. 3 and FIG. 4 show a cross-section through a conventional circuit board.

FIG. 5A, FIG. 5B, FIG. 5C, FIG. 5D, FIG. 5E, FIG. 5F, FIG. 5G, and FIG. 5H respectively show a method of manufacturing a component carrier, according to an exemplary embodiment of the disclosure.

### DETAILED DESCRIPTION OF ILLUSTRATED EMBODIMENTS

The illustrations in the drawings are schematically presented. In different drawings, similar or identical elements are provided with the same reference signs.

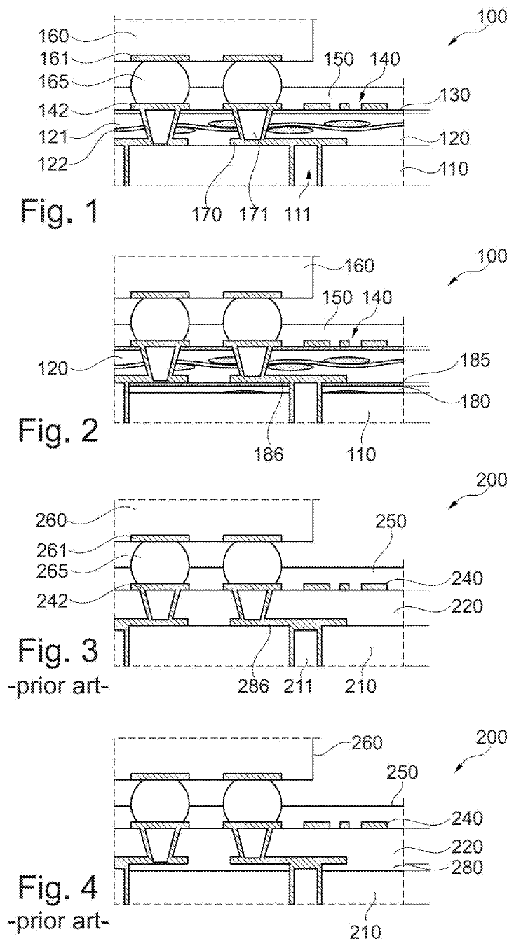

FIG. 1 shows a cross-section through a component carrier 100, according to an exemplary embodiment of the invention. The component carrier 100 comprises a stack with an inorganic carrier structure 110 at the base (a potential base structure beneath the inorganic carrier structure 110 is not shown in this example), which is configured in this example as a glass core layer. Directly on top of the inorganic carrier structure 110, there is arranged an electrically insulating layer structure 120 which comprises a resin matrix 121 with embedded reinforcing structures 122, preferably glass fibers. Directly on top of said reinforced electrically insulating layer structure 120, there is further formed an ultra-thin insulation film 130, for example a mixture of a thermosetting resin, a reactive (low polar) polymer, and an inorganic filler. Further, directly on said ultra-thin insulation film 130, there is formed an electrically conductive layer structure 140 with a fine line pattern.

The ultra-thin insulation film 130 has a thickness in a range from 2 μm to 15 μm (here 4 μm) and a first surface roughness higher than a second surface roughness of the electrically insulating layer structure 120.

The fine line pattern of the electrically conductive layer structure 140 comprises traces having a width in a range from 3 μm to 15 μm. Further, the fine line pattern of the electrically conductive layer structure 140 has a thickness in a range from 3 μm to 15 μm.

The component carrier 100 (stack) further comprises a solder resist layer structure 150 arranged (directly) on the fine line pattern of the electrically insulating layer structure 140, so that the fine line pattern is embedded (encapsulated) in the solder resist layer structure material 150. Said solder resist layer structure 150 has a thickness in a range from 5 μm to 20 μm.

Further, an electronic component 160 (e.g., a semiconductor element such as an IC chip) is surface mounted to the component carrier 100 and electrically coupled with the fine line pattern of the electrically insulating layer structure 140 and/or the electrically conductive layer structure connection 142 (for example a pad) by an electrically conductive connection structure, here a solder ball structure 165.

The component carrier 100 further comprises an electrically conductive vertical through-connection 111, extending through the inorganic carrier structure 110, the electrically insulating layer structure 120, and the ultra-thin insulation film 130 to electrically connect to a trace of the fine line pattern of the electrically conductive layer structure 140.

In the illustrated example, said electrically conductive vertical through-connection 111 is realized by the following elements: i) a through-via 111 that extends through the inorganic carrier structure 110, ii) an electrically conductive pad 170 directly on top of the inorganic carrier structure 110 and embedded in material of the electrically insulating layer structure 120, iii) a blind via 171 that extends through the electrically insulating layer structure 120 and the ultra-thin insulation film 130 and is directly connected to the fine line pattern of the electrically conductive layer structure 140.

At an interface between the electrically insulating layer structure 120 and the ultra-thin insulation film 130, an intermingling region (not shown) can be formed, wherein the intermingling region comprises a mixture of material of the electrically insulating layer structure and material of the ultra-thin insulation film.

FIG. 2 shows a cross-section through a component carrier 100, according to an exemplary embodiment of the invention, with a further electrically insulating layer structure 180 (comprising a further resin and further reinforcing structures) and a further ultra-thin insulation film 185 on said further electrically insulating layer structure 180. The further electrically insulating layer structure 180 and the further ultra-thin insulation film 185 are arranged between the inorganic carrier structure 110 and the electrically insulating layer structure 120. In this manner, the above-described electrically conductive pads 170 are not arranged directly on the inorganic carrier structure but are formed as a further electrically conductive layer structure 186 directly on the further ultra-thin insulation film 185. At an interface between the electrically insulating layer structure 120 and the ultra-thin insulation film 130 and/or the further ultra-thin insulation film 185, an intermingling region can be present that comprises a mixture of material of the electrically insulating layer structure 120 and material of the ultra-thin insulation film 130 and/or the further ultra-thin insulation film 185. The two materials might penetrate with each other, so there might be a merge surface or surface to surface interface between the two layers where one material can protrude into the other material.

The through hole 111 through the inorganic carrier structure 110 protrudes further from the surface of the inorganic carrier structure 110, then through the further electrically insulating layer structure 180 and the further ultra-thin insulation film 185. This structure might improve the adhesion, in particular when the further electrically insulating layer structure 180 is directly on the inorganic carrier structure 110, and also might realize the fine line pattern of the further electrically conductive layer structure 186 on the further ultra-thin insulation film 185.

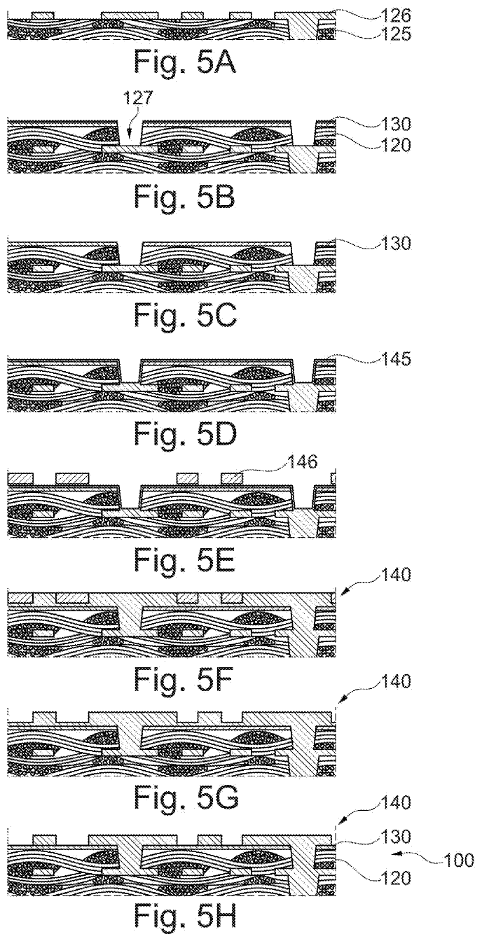

FIG. 5A, FIG. 5B, FIG. 5C, FIG. 5D, FIG. 5E, FIG. 5F, FIG. 5G, and FIG. 5H respectively show a method of manufacturing a component carrier 100 using a pSAP process, according to an exemplary embodiment of the invention.

As illustrated in FIG. 5A, there is provided an electrically insulating core layer 125 with a patterned metal structure 126. The core layer 125 can be an inorganic carrier structure 110 or can be formed on such an inorganic carrier structure 110.

As illustrated in FIG. 5B, an electrically insulating layer structure 120 (reinforced) is formed by lamination on the core layer 125 (e.g., as a prepreg). Then, an ultra-thin insulation film 130 (with a thin metal layer on top) is formed/laminated on the electrically insulating layer structure 120. Holes 127 are drilled through the electrically insulating layer structure 120 and the ultra-thin insulation film 130 down to the patterned metal structure 126.

As illustrated in FIG. 5C, the thin metal (copper) layer on top of the ultra-thin insulation film 130 is removed by etching.

As illustrated in FIG. 5D, the ultra-thin insulation film 130 is used as a primer for forming an electroless plating layer 145 (copper). Hereby, also the sidewalls of the holes 127 are plated.

As illustrated in FIG. 5E, a dielectric pattern film (negative mask) 146 is arranged on the plating layer 145.

As illustrated in FIG. 5F, the spaces in between the dielectric pattern film 146 and the holes 127 are completely filled with metal (copper) by plating, thereby forming an electrically conductive layer structure 140 with a fine line pattern structure.

As illustrated in FIG. 5G, the dielectric pattern film 146 is removed (stripped).

As illustrated in FIG. 5H, using flash etching, copper residues between the traces of the electrically conductive layer structure 140 are removed to expose the ultra-thin insulation film 130 below. In a further step (not shown), the solder resist layer structure 150 can be provided.

It should be noted that the term “comprising” does not exclude other elements or steps and the article “a” or “an” does not exclude a plurality. Also, elements described in association with different embodiments may be combined.

Implementation of the disclosure is not limited to the preferred embodiments shown in the figures described above. Instead, a multiplicity of variants are possible which variants use the solutions shown and the principle according to the disclosure even in the case of fundamentally different embodiments.

### Reference Signs

100 Component carrier
110 Inorganic carrier structure
111 Electrically conductive vertical through-connection
120 Electrically insulating layer structure
121 Resin
122 Reinforcing fibers
125 Core layer
126 Patterned metal structure
130 Ultra-thin insulation film
140 Electrically conductive layer structure with fine line pattern
142 Electrically conductive layer structure connection
145 Plating layer
146 Dielectric film with pattern
150 Solder resist layer structure
160 Electronic component, IC
161 Electronic component electric connection
165 Solder structure/ball
170 Further electrically conductive layer structure
171 Further electrically conductive vertical through-connection
180 Further electrically insulating layer structure
185 Further ultra-thin insulation film
186 Further electrically conductive layer structure

1. A component carrier, comprising:
an inorganic carrier structure;
an electrically insulating layer structure comprising resin and reinforcing structures on the inorganic carrier structure;
an ultra-thin insulation film on the electrically insulating layer structure; and
an electrically conductive structure with a fine line pattern directly on the ultra-thin insulation film.

2. The component carrier according to claim 1, wherein the inorganic carrier structure comprises at least one of: a glass, a ceramic, a semiconductor material.

3. The component carrier according to claim 1,
wherein the resin of the electrically insulating layer structure comprises an epoxy resin.

4. The component carrier according to claim 1,
wherein the reinforcing structures of the electrically insulating layer structure comprise reinforcing fibres, in particular glass fibres, more in particular glass cloth.

5. The component carrier according to claim 1,
wherein the ultra-thin insulation film has a thickness in a range from 2 μm to 15 μm.

6. The component carrier according to claim 1,
wherein the ultra-thin insulation film has a first surface roughness higher than a second surface roughness of the electrically insulating layer structure and/or higher than a third surface roughness of the electrically conductive fine line pattern.

7. The component carrier according to claim 1,
wherein the ultra-thin insulation film is formed in contact with, in particular directly on, the electrically insulating layer structure.

8. The component carrier according to claim 1,
wherein the fine line pattern of the electrically conductive layer structure comprises at least one trace having a width in a range from 3 μm to 15 μm.

9. The component carrier according to claim 1,
wherein the fine line pattern of the electrically conductive layer structure has a thickness in a range from 3 μm to 15 μm.

10. The component carrier according to claim 1,
wherein the electrically insulating layer structure is formed directly on the inorganic carrier structure.

11. The component carrier according to claim 1, further comprising:
a surface-mounted electronic component being electrically coupled with the fine line pattern of the electrically insulating layer structure by an electrically conductive connection structure, in particular a solder structure.

12. The component carrier according to claim 1, further comprising:
a solder resist layer structure arranged on the fine line pattern of the electrically insulating layer structure, in particular wherein the solder resist layer structure has a thickness in a range from 5 μm to 20 μm.

13. The component carrier according to claim 1, further comprising:
a second electrically insulating layer structure comprising a second resin and a second reinforcing structures;
a second ultra-thin insulation film on said second electrically insulating layer structure, in particular wherein the second electrically insulating layer structure and the second ultra-thin insulation film are arranged between the inorganic carrier structure and the electrically insulating layer structure.

14. The component carrier according to claim 1, further comprising:
an electrically conductive vertical through-connection extending through at least one of the inorganic carrier structure, the electrically insulating layer structure, the ultra-thin insulation film.

15. The component carrier according to claim 1, further comprising:
an intermingling region at an interface between the electrically insulating layer structure and the ultra-thin insulation film, wherein the intermingling region comprises a mixture of material of the electrically insulating layer structure and material of the ultra-thin insulation film.

16. The component carrier according to claim 1, further comprising:
a base structure beneath the inorganic carrier structure.

17. The component carrier according to claim 1, wherein the ultra-thin insulation film comprises at least one of the following materials: a polymer, in particular a resin, a filler.

18. A method of manufacturing a component carrier, the method comprising:
providing an inorganic carrier structure;
applying an electrically insulating layer structure, which comprises resin and reinforcing structures, on the inorganic carrier structure;
applying an ultra-thin insulation film on the electrically insulating layer structure; and
forming an electrically conductive layer structure with a fine line pattern directly on the ultra-thin insulation film.

19. The method according to claim 18, further comprising:
applying an electrically conductive material for forming the electrically conductive layer structure with the fine line pattern on the ultra-thin insulation film by at least one of electroless deposition, plating, sputtering, laminating a metal foil.

20. The method according to claim 18, further comprising:
applying the ultra-thin insulation film in an at least partially uncured state.
